(19) United States
(12) Patent Application Publication
(10) Pub. No.: US 2026/0203600 A1
(43) Pub. Date: Jul. 16, 2026

(54) NEURON DEVICE FOR PERFORMING BINARY LOGIC OPERATION

(71) Applicant: KOREA INSTITUTE OF SCIENCE AND TECHNOLOGY, Seoul (KR)

(72) Inventors: Suyoun LEE, Seoul (KR); Kyungreem HAN, Seoul (KR); Junhyuk WOO, Seoul (KR); Jaesang LEE, Yongin-si (KR); Unhyeon KANG, Seoul (KR)

(73) Assignee: KOREA INSTITUTE OF SCIENCE AND TECHNOLOGY, Seoul (KR)

(21) Appl. No.: 19/408,737

(22) Filed: Dec. 4, 2025

(30) Foreign Application Priority Data
Jan. 15, 2025 (KR) 10-2025-0006341

(51) Int. Cl. G06N 3/10; H03K 19/21

(52) U.S. Cl. CPC G06N 3/10; H03K 19/21

(57) ABSTRACT

The present disclosure relates to a neuron device of a spiking neural network, and the neuron device performs a binary logic operation on multiple input signals using an Ovonic threshold switch that simulates generation of a spike signal according to accumulation of at least one input signal among the multiple input signals input through multiple resistors that serve as multiple dendrites.

### CROSS-REFERENCE TO RELATED APPLICATION

This application is based on and claims priority under 35 U.S.C. §119 to Korean Patent Application No. 10-2025-0006341, filed on January 15, 2025, in the Korean Intellectual Property Office, the disclosure of which is incorporated by reference herein in its entirety.

### BACKGROUND

The present disclosure relates to a neuron device of a spiking neural network.

An application field of an artificial neural network, such as deep neural network (DNN) is expanded to a medical field such as drug design and disease diagnosis, a financial field such as stock price prediction and credit rating, and an environmental field such as climate change prediction and disaster management, beyond traditional applications, such as computer vision, natural language processing, and voice recognition. Accordingly, the type of data processed by artificial neural networks is diversified, and complexity of data is increased significantly. Due to this, the number of neurons and hidden layers in each layer of the artificial neural network has increased exponentially, and as a result, power consumption of the artificial neural network rapidly increases.

Recently, neuromorphic computing, which may significantly reduce power consumption by imitating an operating method of biological neurons and synapses, has been attracting attention. A spiking neural network (SNN) is a core technology in the field of neuromorphic computing, which may reduce power consumption by processing signals using a spike-based asynchronous calculation method. It is known that, in biological brains, neurons that encode information input from the outside in analog method coexist with neurons that encode in a binary method. However, a neuron device that may perform a binary logic operation in a spiking neural network has not developed yet.

### SUMMARY

The present disclosure provides a neuron device that may perform a binary logic operation in a spiking neural network. The present disclosure is not limited to the technical tasks described above, and other technical tasks may be derived from the following description.

According to an aspect, a neuron device of a spiking neural network includes an Ovonic threshold switch configured to simulate generation of a spike signal according to accumulation of at least one input signal among multiple input signals input through multiple resistors that serve as multiple dendrites, wherein a binary logic operation is performed on the multiple input signals using the Ovonic threshold switch.

The neuron device further includes a capacitor that is charged according to a voltage of each of the multiple input signals, wherein the Ovonic threshold switch may simulate the generation of the spike signal according to the accumulation of the at least one input signal among the multiple input signals by switching from an off state to an on state according to a charging voltage of the capacitor.

The capacitor may be connected between a first terminal of two terminals of the Ovonic threshold switch and a ground of the spiking neural network.

The neuron device may further include a first resistor configured to function as a first dendrite among the multiple dendrites by receiving a first input signal among the multiple input signals through one end of the first resistor, and a second resistor configured to function as a second dendrite among the multiple dendrites by receiving a second input signal among the multiple input signals through one end of the second resistor.

The neuron device may further include a third resistor connected between a second terminal among two terminals of the Ovonic threshold switch and the ground of the spiking neural network and configured to adjust a refractory period length of the Ovonic threshold switch.

A first terminal of two terminals of the capacitor may be connected to a first terminal among the two terminals of the Ovonic threshold switch, and a second terminal of the two terminals of the capacitor may be connected to the ground of the spiking neural network, another end of the first resistor may be connected to a first node corresponding to a connection point between the first terminal of the Ovonic threshold switch and the first terminal of the capacitor, and another end of the second resistor may be connected to the first node in parallel with the first resistor, and a voltage of a second node corresponding to a connection point between the second terminal of the Ovonic threshold switch and one end of the third resistor may represent a result value of an AND operation on the multiple input signals.

A first terminal of two terminals of the capacitor may be connected to the first terminal of the two terminals of the Ovonic threshold switch, a second terminal of the two terminals of the capacitor may be connected to the ground of the spiking neural network, the neuron device may further include a first diode connected between the first node corresponding to the connection point between the first terminal of the Ovonic threshold switch and the first terminal of the capacitor and another end of the first resistor and allowing a current to flow in a direction from another end of the first resistor toward the first node; and a second diode connected between the first node and another end of the second resistor and allowing a current to flow in a direction from the other end of the second resistor toward the first node, and a voltage of a second node corresponding to a connection point between the second terminal of the Ovonic threshold switch and one end of the third resistor may represent a result value of an OR operation on the multiple input signals.

A first terminal of two terminals of the capacitor may be connected to the first terminal of the two terminals of the Ovonic threshold switch, the neuron device may further include a fourth resistor having one end connected to the second terminal of the two terminals of the capacitor and another end connected to the ground of the spiking neural network, another end of the first resistor may be connected to a first node corresponding to a connection point of the first terminal of the Ovonic threshold switch and the first terminal of the capacitor, and another end of the second resistor may be connected to the first node in parallel with the first resistor, and a voltage of a second node corresponding to a connection point between the second terminal of the capacitor and one end of the fourth resistor may represent a result value of a NOR operation on values of the multiple input signals.

The neuron device may further include a fifth resistor having one end connected to a third node corresponding to a connection point between the second terminal of the Ovonic threshold switch and one end of the third resistor, and an external voltage for turning on the Ovonic threshold switch may be applied to another end of the fifth resistor.

A first terminal of two terminals of the capacitor may be connected to the first terminal of the two terminals of the Ovonic threshold switch, the neuron device may further include a first diode connected between a first node corresponding to a connection point between the first terminal of the Ovonic threshold switch and a first terminal of the capacitor and another terminal of the first resistor, and allowing only a current to flow in a direction from the first node toward the other terminal of the first resistor; a second diode connected between the first node and another terminal of the second resistor and allowing only a current to flow in a direction from the first node to the other terminal of the second resistor; and a fourth resistor having one end connected to a second terminal of the two terminals of the capacitor and another end connected to the ground of the spiking neural network, and a voltage of a second node corresponding to a connection point of the second terminal of the capacitor and one end of the fourth resistor may represent a result value of a NAND operation on values of the multiple input signals.

The neuron device may further include a fifth resistor having one end connected to a third node corresponding to a connection point between the second terminal of the Ovonic threshold switch and one end of the third resistor, and an external voltage for turning on the Ovonic threshold switch may be applied to another end of the fifth resistor.

The capacitor may be a first capacitor, the neuron device may further include a second capacitor connected between the second terminal of the Ovonic threshold switch and the third resistor, another end of the second resistor may be connected to a first node corresponding to a connection point between the first terminal of the Ovonic threshold switch and a first terminal of two terminals of the first capacitor, another end of the first resistor may be connected to a second node corresponding to a connection point between the second terminal of the Ovonic threshold switch and a first terminal of two terminals of the second capacitor, and a voltage of a third node corresponding to a connection point between a second terminal of the second capacitor and one end of the third resistor may represent a result value of an XOR operation on values of the multiple input signals.

### BRIEF DESCRIPTION OF THE DRAWINGS

Embodiments will be more clearly understood from the following detailed description taken in conjunction with the accompanying drawings in which:

FIG. 1 is a circuit diagram of a neuron device, which performs an AND operation, according to an embodiment of the present disclosure;

FIG. 2 is a voltage waveform diagram for input/output of the neuron device illustrated in FIG. 1;

FIG. 3 is a circuit diagram of a neuron device, which performs an OR operation, according to another embodiment of the present disclosure;

FIG. 4 is a voltage waveform diagram for input/output of the neuron device illustrated in FIG. 3;

FIG. 5 is a circuit diagram of a neuron device, which performs a NOR operation, according to another embodiment of the present disclosure;

FIG. 6 is a voltage waveform diagram for input/output of the neuron device illustrated in FIG. 5;

FIG. 7 is a circuit diagram of a neuron device, which performs a NAND operation, according to another embodiment of the present disclosure;

FIG. 8 is a voltage waveform diagram for input/output of the neuron device illustrated in FIG. 7;

FIG. 9 is a circuit diagram of a neuron device, which performs an XOR operation, according to another embodiment of the present disclosure; and

FIG. 10 is a voltage waveform diagram for input/output of the neuron device illustrated in FIG. 9.

### DETAILED DESCRIPTION OF THE EMBODIMENTS

Hereinafter, embodiments of the present disclosure are described in detail with reference to the drawings.

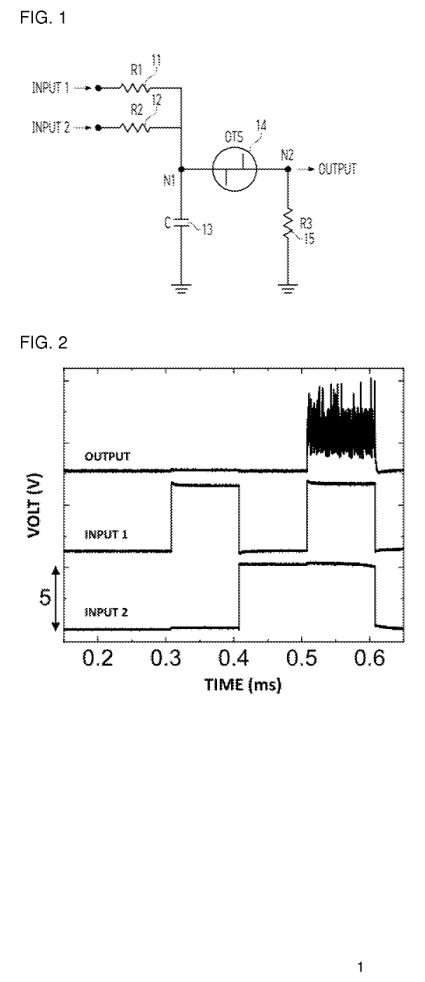

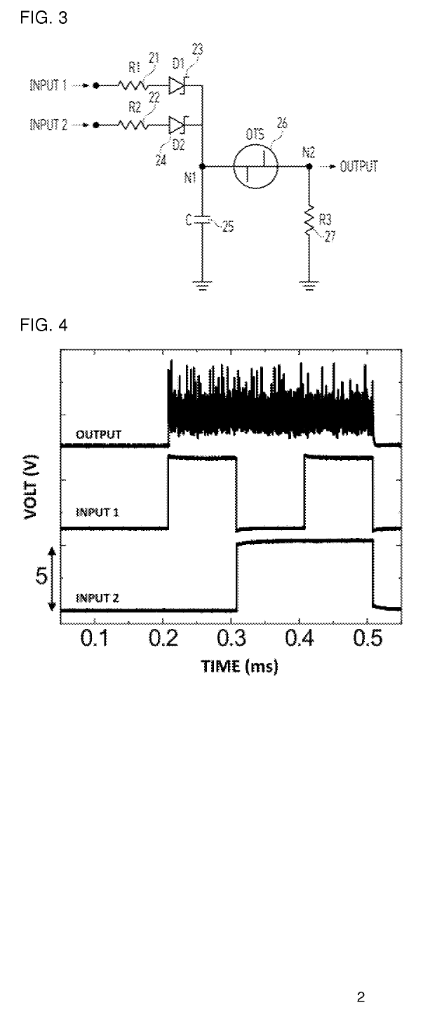

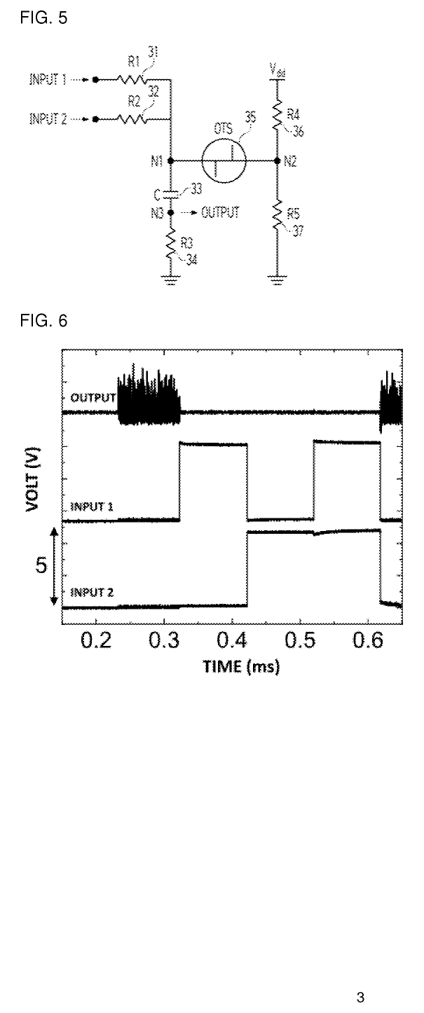

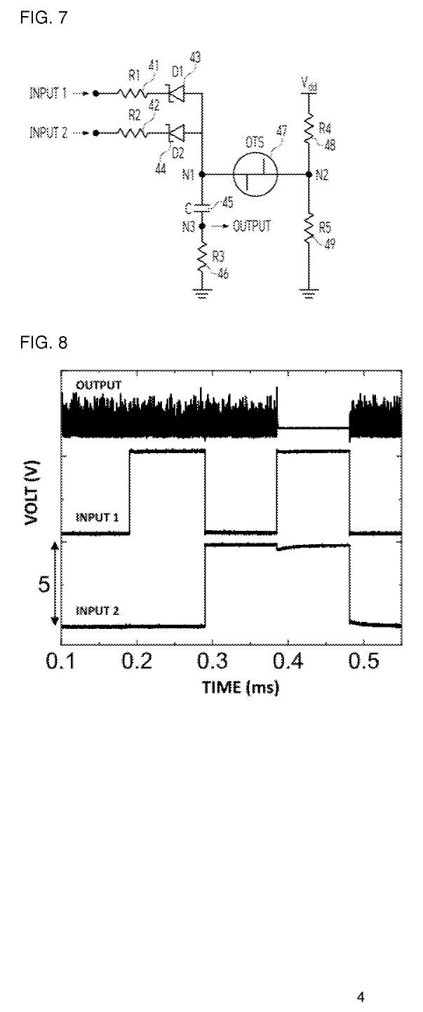

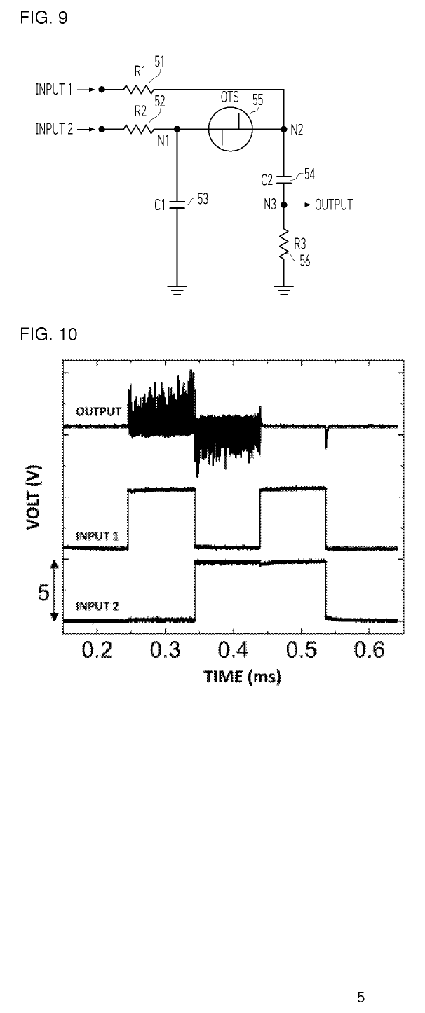

FIG. 1 is a circuit diagram of a neuron device, which performs an AND operation, according to one embodiment of the present disclosure, and FIG. 2 is a voltage waveform diagram for input and output of the neuron device illustrated in FIG. 1. FIG. 3 is a circuit diagram of a neuron device, which performs an OR operation, according to another embodiment of the present disclosure, and FIG. 4 is a voltage waveform diagram for input and output of the neuron device illustrated in FIG. 3. FIG. 5 is a circuit diagram of a neuron device, which performs a NOR operation, according to another embodiment of the present disclosure, and FIG. 6 is a voltage waveform diagram for input and output of the neuron device illustrated in FIG. 5. FIG. 7 is a circuit diagram of a neuron device, which performs a NAND operation, according to another embodiment of the present disclosure, and FIG. 8 is a voltage waveform diagram for input and output of the neuron device illustrated in FIG. 7. FIG. 9 is a circuit diagram of a neuron device, which performs an XOR operation, according to another embodiment of the present disclosure, and FIG. 10 is a voltage waveform diagram for input and output of the neuron device illustrated in FIG. 9.

The neuron devices illustrated in FIGS. 1, 3, 5, 7, and 9, may be used as neuron devices of a spiking neural network that perform binary logic operations. The spiking neural network is a neural network that mimics operations of biological neurons, and processes signals in a spike-based asynchronous computational method, unlike the conventional artificial neural network. In the biological neurons, a stimulus signal input through dendrites is accumulated in a membrane potential, and when the membrane potential reaches a threshold voltage, the neurons fire and generate a spike signal, and after the spike signal is generated, there is a refractory period during which a new stimulus signal is not fired until the membrane potential reaches the threshold voltage again. An operation model of the biological neurons is called a leaky integrate-and-fire (LIF) model.

The neuron devices illustrated in FIGS. 1, 3, 5, 7, and 9, perform binary logic operations on multiple input signals using an Ovonic threshold switch that simulates the generation of a spike signal according to the accumulation of at least one input signal among multiple input signals input through multiple resistors that function as multiple dendrites. The Ovonic threshold switch is made of an amorphous semiconductor material and normally maintains a high resistance state. When a voltage applied between two terminals of the Ovonic Threshold Switch exceeds a threshold voltage, resistance between the two terminals rapidly decreases, and a switch is switched from an off state to an on state. When the voltage applied between the two terminals of the ovonic threshold switch decreases below the threshold voltage, the resistance between the two terminals increases rapidly to an original state.

The neuron devices illustrated in FIGS. 1, 3, 5, 7, and 9, perform binary logic operations based on simulation of the LIF operation of the biological neuron described above, using characteristics of the Ovonic threshold switch. A spike signal generated from a neuron is transmitted to another neuron, thereby transmitting neural network information. Hereinafter, a neuron device that performs an AND operation, a neuron device that performs an OR operation, a neuron device that performs a NOR operation, a neuron device that performs a NAND operation, and a neuron device that performs an XOR operation will be described in detail. The "Ovonic threshold switch" is abbreviated as "OTS".

Referring to FIG. 1, a neuron device that performs an AND operation is composed of a resistor R1 (11), a resistor R2 (12), a capacitor C (13), an OTS 14, and a resistor R3 (15). In FIG. 1, a node corresponding to a connection point between a first terminal of two terminals of the OTS 14 and a first terminal of two terminals of the capacitor C (13) is referred to as "N1", and a node corresponding to a connection point between a second terminal of the two terminals of the OTS 14 and one end of the resistor R3 (15) is referred to as "N2".

A first input signal among multiple input signals is input through one end of the resistor R1 (11), and the resistor R1 (11) functions as a first dendrite among multiple dendrites. A second input signal among the multiple input signals is input through one end of the resistor R2 (12), and the resistor R2 (12) functions as a second dendrite among the multiple dendrites. Because voltage drops occur while the respective input signals pass through the two resistors 11 and 12, the respective resistors 11 and 12 may simulate a phenomenon in which an external signal is weakened while passing through the dendrite of a biological neuron. In the neuron device illustrated in FIG. 1, the other end of the resistor R1 (11) is connected to the node "N1", and the other end of the resistor R2 (12) is connected to node "N1" in parallel with the resistor R1 (11).

The capacitor C (13) is connected between the first terminal of OTS 14 and the ground of a spiking neural network, and electric charges are accumulated in the capacitor C (13) according to a voltage of each of the multiple input signals. Charging of the capacitor C (13) may simulate a phenomenon in which a stimulus signal input through the dendrite accumulates in a membrane potential. In the neuron device illustrated in FIG. 1, a first terminal of two terminals of the capacitor C (13) is connected to the first terminal of the OTS 14, that is, the node "N1", and a second terminal of the two terminals of the capacitor C (13) is connected to the ground of the spiking neural network.

The first terminal of the OTS 14 is connected to the first terminal of the capacitor C (13), and the OTS 14 is switched an off state to an on state according to a charging voltage of the capacitor C (13), and accordingly, the OTS 14 simulates the generation of a spike signal according to the accumulation of at least one input signal among the multiple input signals. When a voltage applied to two terminals of the OTS 14 increases and reaches a threshold voltage of the OTS 14, the OTS 14 switches from an off state to an on state. In the neuron device illustrated in FIG. 1, the first terminal of two terminals of the OTS 14 is connected to the first terminal of the capacitor C (13), that is , the node "N1", and the second terminal of two terminals of OTS 14 is connected to one end of the resistor R3 (15), that is, a node "N2".

The resistor R3 (15) is connected between the second terminal of the OTS 14 and the ground of the spiking neural network and serves to control a refractory period length of the OTS 14. Since a voltage between the two terminals of the OTS 14 is determined according to resistance of the resistor R3 (15), the refractory period length of the OTS 14 may be adjusted. In the neuron device illustrated in FIG. 1, one end of the resistor R3 (15) is connected to the second terminal of OTS 14, that is, the "N2", and the other end of the resistor R3 (15) is connected to the ground of the spiking neural network. A voltage of node "N2" represents a result value of an AND operation on multiple input signals.

Among three voltage waveforms illustrated in FIG. 2, an upper voltage waveform represents a voltage waveform of the node "N2", a middle voltage waveform represents a voltage waveform of a signal input to one end of the resistor R1 (11), and a lower voltage waveform represents a voltage waveform of a signal input to one end of the resistor R2 (12). The three voltage waveforms are voltage waveforms measured based on the ground of the spiking neural network, and a maximum amplitude is 5-V. The upper voltage waveform represents a voltage waveform measured between the node "N2" and the ground of the spiking neural network, the middle voltage waveform represents a voltage waveform measured between one end of the resistor R1 (11) and the ground of the spiking neural network, and the lower voltage waveform represents a voltage waveform measured between one end of the resistor R2 (12) and the ground of the spiking neural network.

When both a first input signal input through one end of the resistor R1 (11) and a second input signal input through one end of the resistor R2 (12) are in a low state (0 V), a 0-V signal is input to the node "N1". When either the first input signal input through one end of the resistor R1 (11) or the second input signal input through one end of the resistor R2 (12) is in a low state and the other is in a high state (5 V), a 2.5-V signal is input to node the "N1". Like this, when at least one of the first input signal input through one end of the resistor R1 (11) and the second input signal input through one end of the resistor R2 (12) is in a low state (0 V), a 0-V signal or a 2.5-V signal is input to the node "N1". For this, resistances of two resistors 11 and 12 are designed to be equal to each other.

When a 0-V signal is input to the node "N1", a voltage of the node "N1" is 0 V, and accordingly, the capacitor C (13) is not charged. When a 2.5-V signal is input to the node "N1", the capacitor C (13) is charged, and thereby, a charging voltage of the capacitor C (13) gradually increases and converges to 2.5 V. As illustrated in FIG. 1, a voltage between two terminals of the OTS 14 is a difference voltage between a voltage of the node "N1" and a voltage of the node "N2". Since the voltage of the node "N1" is equal to the charging voltage of the capacitor C (13), when a 0-V signal or a 2.5-V signal is input to the node "N1", a voltage between two terminals of the OTS 14 is less than the threshold voltage of the OTS 14, and accordingly, the OTS 14 turns off. The threshold voltage of the OTS 14 is designed to be less than 5 V and greater than 2.5 V. When the OTS 14 turns off, the voltage of node "N2" is low.

When both the first input signal input through one end of the resistor R1 (11) and the second input signal input through one end of the resistor R2 (12) are in a high state (5 V), a 5-V signal is input to the node "N1". When a 5-V signal is input to the node "N1", the capacitor C (13) is charged, and a charging voltage of the capacitor C (13) gradually increases and converges to 5 V. During an increase in the charging voltage of the capacitor C (13), when a voltage between two terminals of the OTS 14 reaches a threshold voltage, the OTS 14 switches from an off state to an on state. In this case, a spike signal is generated at the node "N2" as the OTS 14 switches from the off state to the on state. As illustrated in FIG. 2, a spike signal generated at the node "N2" has a voltage waveform similar to a waveform in a high state of a signal input through each of the resistors 11 and 12.

As illustrated in FIG. 2, when at least one of a signal input to one end of the resistor R1 (11) and a signal input to one end of the resistor R2 (12) is in a low state, a voltage of the node "N2" is low. Only when the signal input to one end of the resistor R1 (11) is in a high state and the signal input to one end of the resistor R2 (12) is in a high state, the spike signal is generated at the node "N2", and thereby, the voltage of the node "N2" is high. In this way, the neuron device illustrated in FIG. 1 performs an AND operation on a signal input to one end of the resistor R1 (11) and a signal input to one end of the resistor R2 (12).

Referring to FIG. 3, the neuron device that performs an OR operation is composed of a resistor R1 (21), a resistor R2 (22), a diode D1 (23), a diode D2 (24), a capacitor C (25), an OTS (26), and a resistor R3 (27). In FIG. 3, a node corresponding to a connection point between a first terminal of two terminals of the OTS 26 and a first terminal of two terminals of the capacitor C (25) is referred to as "N1", and a node corresponding to a connection point between a second terminal of the two terminals of the OTS 26 and one end of the resistor R3 (27) is referred to as "N2".

A first input signal among multiple input signals is input through one end of the resistor R1 (21), and the resistor R1 (21) functions as a first dendrite among multiple dendrites. A second input signal among the multiple input signals is input through one end of the resistor R2 (22), and the resistor R2 (22) functions as a second dendrite among the multiple dendrites. Because voltage drops occur while the respective input signals pass through the two resistors 21 and 22, the respective resistors 21 and 22 may simulate a phenomenon in which an external signal is weakened while passing through the dendrite of a biological neuron. In the neuron device illustrated in FIG. 3, the other end of the resistor R1 (21) is connected to a positive terminal of the diode D1 (23), and the other end of the resistor R2 (22) is connected to a positive terminal of the diode D2 (24).

Diode D1 (23) is connected between the node "N1" and the other end of the resistor R1 (21) and allows only a current to flow in a direction from the other end of the resistor R1 (21) toward the node "N1". The diode D2 (24) is connected between the node "N1" and the other end of the resistor R2 (22) and allows only a current to flow in a direction from the other end of the resistor R2 (22) toward the node "N1". In the neuron device illustrated in FIG. 3, the positive terminal of the diode D1 (23) is connected to the other end of the resistor R1 (21), and the negative terminal of the diode D1 (23) is connected to the node "N1". The positive terminal of the diode D2 (24) is connected to the other end of the resistor R2 (22), and the negative terminal of the diode D2 (24) is connected to node "N1".

The capacitor C (25) is connected between the first terminal of OTS 26 and the ground of a spiking neural network, and electric charges are accumulated in the capacitor C (25) according to a voltage of each of the multiple input signals. Charging of the capacitor C (25) may simulate a phenomenon in which a stimulus signal input through the dendrite accumulates in a membrane potential. In the neuron device illustrated in FIG. 3, a first terminal of two terminals of the capacitor C (25) is connected to the first terminal of the OTS 26, that is, the node "N1", and a second terminal of the two terminals of the capacitor C (25) is connected to the ground of the spiking neural network.

The first terminal of the OTS 26 is connected to the first terminal of the capacitor C (25), and the OTS 26 is switched an off state to an on state according to a charging voltage of the capacitor C (25), and accordingly, the OTS 26 simulates the generation of a spike signal according to the accumulation of at least one input signal among the multiple input signals. When a voltage applied to two terminals of the OTS 26 increases and reaches a threshold voltage of the OTS 26, the OTS 26 switches from an off state to an on state. In the neuron device illustrated in FIG. 3, the first terminal of two terminals of the OTS 26 is connected to the first terminal of the capacitor C (25), that is , the node "N1", and the second terminal of two terminals of OTS 26 is connected to one end of the resistor R3 (27), that is, a node "N2".

The resistor R3 (27) is connected between the second terminal of the OTS 26 and the ground of the spiking neural network and serves to control a refractory period length of the OTS 26. Since a voltage between the two terminals of the OTS 26 is determined according to resistance of the resistor R3 (27), the refractory period length of the OTS 26 may be adjusted. In the neuron device illustrated in FIG. 3, one end of the resistor R3 (27) is connected to the second terminal of OTS 26, that is, the "N2", and the other end of the resistor R3 (27) is connected to the ground of the spiking neural network. A voltage of node "N2" represents a result value of an OR operation on multiple input signals.

Among three voltage waveforms illustrated in FIG. 4, an upper voltage waveform represents a voltage waveform of the node "N2", a middle voltage waveform represents a voltage waveform of a signal input to one end of the resistor R1 (21), and a lower voltage waveform represents a voltage waveform of a signal input to one end of the resistor R2 (22). The three voltage waveforms are voltage waveforms measured based on the ground of the spiking neural network, and a maximum amplitude is 5 V. The upper voltage waveform represents a voltage waveform measured between the node "N2" and the ground of the spiking neural network, the middle voltage waveform represents a voltage waveform measured between one end of the resistor R1 (21) and the ground of the spiking neural network, and the lower voltage waveform represents a voltage waveform measured between one end of the resistor R2 (22) and the ground of the spiking neural network.

A first input signal input through one end of the resistor R1 (21) flows only in a direction of the node "N1" through the diode D1 (23), and a second input signal input through one end of the resistor R2 (22) flows only in a direction of the node "N1" through the diode D2 (24). Accordingly, when at least one of the first input signal input through one end of the resistor R1 (21) and the second input signal input through one end of the resistor R2 (22) is in a high state (5 V), a 5-V signal is input to the node "N1". In a state where the 5-V signal is input to the node "N1", the capacitor C (25) is charged, and a charging voltage of the capacitor C (25) gradually increases and converges to 5 V.

While a voltage between two terminals of the OTS (26) reaches a threshold voltage while the charging voltage of the capacitor C (25) increases, the OTS 26 switches from an off state to an on state. In this case, as the OTS (26) switches from the off state to the on state, a spike signal is generated at the node "N2". A threshold voltage of OTS 26 is designed to be less than 5 V and greater than 2.5V. As illustrated in FIG. 4, a spike signal generated at the node "N2" has a voltage waveform similar to a waveform in a high state of a signal input through each of the resistors 12 and 22.

When both the first input signal input through one end of resistor R1 (21) and the second input signal input through one end of the resistor R2 (22) are in a low state, a 0-V signal is input to the node "N1". When the 0-V signal is input to the node "N1", a voltage of node "N1" is 0 V, and the capacitor C (25) is not charged. When the voltage of node "N1" is 0 V, a voltage between two terminals of the OTS 26 is less than the threshold voltage of OTS 26, and the OTS 26 turns off. When the OTS 26 turns off, a voltage of the node "N2" is low.

As illustrated in FIG. 4, when at least one of a signal input to one end of the resistor R1 (21) and a signal input to one end of the resistor R2 (22) is in a high state, a spike signal is generated at the node "N2" and the voltage of node "N2" increases. The voltage of the node "N2" is low only when the signal input to one end of the resistor R1 (21) is in a low state and the signal input to one end of the resistor R2 (22) is in a low state. In this way, the neuron device illustrated in FIG. 3 performs an OR operation on a signal input to one end of the resistor R1 (21) and a signal input to one end of the resistor R2 (22).

Referring to FIG. 5, a neuron device that performs a NOR operation is composed of a resistor R1 (31), a resistor R2 (32), a capacitor C (33), a resistor R3 (34), an OTS 35, a resistor R4 (36), and a resistor R5 (37). In FIG. 5, a node corresponding to a connection point between a first terminal of two terminals of the OTS 35 and a first terminal of two terminals of the capacitor C (33) is referred to as "N1", a node corresponding to a connection point between a second terminal of the two terminals of the OTS 35 and one end of the resistor R5 (37) is referred to as "N2", and a node corresponding to a connection point between a second terminal of two terminals of the capacitor C (33) and one end of the resistor R3 (34) is referred to as "N3".

A first input signal among multiple input signals is input through one end of the resistor R1 (31), and the resistor R1 (31) functions as a first dendrite among multiple dendrites. A second input signal among the multiple input signals is input through one end of the resistor R2 (32), and the resistor R2 (32) functions as a second dendrite among the multiple dendrites. Because voltage drops occur while the respective input signals pass through the two resistors 31 and 32, the respective resistors 31 and 32 may simulate a phenomenon in which an external signal is weakened while passing through the dendrite of a biological neuron. In the neuron device illustrated in FIG. 5, the other end of the resistor R1 (31) is connected to the node "N1", and the other end of the resistor R2 (32) is connected to the node "N1" in parallel with the resistor R1 (31).

The capacitor C (33) is connected between the first terminal of the OTS 35 and the ground of a spiking neural network, and electric charges are accumulated in the capacitor C (33) according to a voltage of each of the multiple input signals. Charging of the capacitor C (33) may simulate a phenomenon in which a stimulus signal input through the dendrite accumulates in a membrane potential. In the neuron device illustrated in FIG. 5, a first terminal of two terminals of the capacitor C (33) is connected to the first terminal of the OTS 35, that is, the node "N1", and a second terminal of the two terminals of the capacitor C (33) is connected to one end of the resistor R3 (34), that is, a node "N3". The resistor R3 (34) has one end connected to the second terminal of the capacitor C (33), that is, the node "N1", and has the other end connected to the ground of the spiking neural network.

The first terminal of the OTS 35 is connected to the first terminal of the capacitor C (33), and the OTS 35 is switched an off state to an on state according to a charging voltage of the capacitor C (33), and accordingly, the OTS 35 simulates the generation of a spike signal according to the accumulation of at least one input signal among the multiple input signals. When a voltage applied to two terminals of the OTS 35 increases and reaches a threshold voltage of the OTS 35, the OTS 35 switches from an off state to an on state. In the neuron device illustrated in FIG. 5, the first terminal of two terminals of the OTS 35 is connected to the first terminal of the capacitor C (33), that is , the node "N1", and the second terminal of two terminals of OTS 35 is connected to one end of the resistor R5 (37), that is, a node "N2".

One end of the resistor R4 (36) is connected to node "N2", and the other end is applied with an external voltage "Vdd" for turning on OTS 35 such that a voltage exceeding a threshold voltage of OTS 35 is applied to the node "N2". The external voltage "Vdd" may be a drive voltage of a spiking neural network. Since the voltage applied to the node "N2" is determined according to resistance of the resistor R4 (36), a voltage exceeding the threshold voltage of the OTS 35 may be applied to the node "N2".

The resistor R5 (37) is connected between the second terminal of the OTS 35 and the ground of the spiking neural network and serves to adjust a refractory period length of the OTS 35. Since a voltage between the two terminals of the OTS 35 is determined according to resistance of the resistor R5 (37), a refractory period length of the OTS 35 may be adjusted. In the neuron device illustrated in FIG. 5, one end of the resistor R5 (37) is connected to the second terminal of the OTS 35, that is, the node "N2", and the other end of the resistor R5 (37) is connected to the ground of the spiking neural network. A voltage of the node "N3" represents a result value of a NOR operation on multiple input signals.

Among three voltage waveforms illustrated in FIG. 6, an upper voltage waveform represents a voltage waveform of the node "N3", a middle voltage waveform represents a voltage waveform of a signal input to one end of the resistor R1 (31), and a lower voltage waveform represents a voltage waveform of a signal input to one end of the resistor R2 (32). The three voltage waveforms are voltage waveforms measured based on the ground of the spiking neural network, and a maximum amplitude is 5 V. The upper voltage waveform represents a voltage waveform measured between the node "N3" and the ground of the spiking neural network, the middle voltage waveform represents a voltage waveform measured between one end of the resistor R1 (31) and the ground of the spiking neural network, and the lower voltage waveform represents a voltage waveform measured between one end of the resistor R2 (32) and the ground of the spiking neural network.

When at least one of a first input signal input through one end of the resistor R1 (31) and a second input signal input through one end of the resistor R2 (32) is in a high state (5 V), a 2.5-V signal or a 5-V signal is input to the node "N1", and thereby, the capacitor C (33) is charged. For this, resistances of two resistors 31 and 32 are designed to be equal to each other. When the 2.5-V signal is input to the node "N1", electric charges are accumulated in the capacitor C (33), and thereby, a charging voltage of the capacitor C (33) gradually increases and converges to 2.5 V. When a 5-V signal is input to the node "N1", the capacitor C (33) is charged, and thereby, a charging voltage of the capacitor C (33) gradually increases and converges to 5 V.

As illustrated in FIG. 5, a voltage between two terminals of the OTS 35 is a difference voltage between a voltage of the node "N2" and a voltage of the node "N1". Since a voltage exceeding a threshold voltage of the OTS 35 is applied to the node "N2" due to an external voltage "Vdd", in a state where a 2.5-V signal or 5-V signal is input to the node "N1", a voltage between two terminals of the OTS 35 is less than the threshold voltage of the OTS 35, and the OTS 35 turns off. The threshold voltage of the OTS 35 is designed to be less than 5 V and greater than 2.5 V. Since there is no voltage drop between two terminals of the resistor R3 (34) in a state where the charging voltage of the capacitor C (33) converges to 2.5 V or 5 V, a voltage of the node "N3" is low.

When both a first input signal input through one end of the resistor R1 (31) and a second input signal input through one end of the resistor R2 (32) are in low state (O V), a 0-V signal is input to the node "N1" and a voltage of the node "N1" is 0 V. Since a voltage exceeding the threshold voltage of the OTS 35 is applied to the node "N2" due to the external voltage "Vdd", in a state where the voltage of the node "N1" is 0 V, a voltage between two terminals of the OTS 35 exceeds the threshold voltage of the OTS 35, and accordingly, the OTS 35 turns on. As parallel connection resistance of the resistor R1 (31) and the resistor R2 (32) is much greater than resistance of the OTS 35, the OTS 35 turns on, and a voltage drop between two terminals of the resistor R1 (31) and the resistor R2 (32) connected in parallel is greater than a voltage drop between two terminals of the OTS 35, and accordingly, the OTS 35 turns off.

When the OTS 35 turns off, the voltage of the node "N1" is 0 V, and accordingly, the OTS 35 turns on again. In this way, the OTS 35 alternately repeats turning on and turning off, and thereby, voltage oscillation occurs at the node "N1". Due to the voltage oscillation of the node "N1", the capacitor C (33) repeats charging and discharging, and thereby, a spike signal is generated at the node "N3" according to alternate repetition of the turning off and turning on of the OTS 35. As illustrated in FIG. 6, the spike signal generated at the node "N3" has a voltage waveform similar to a waveform in a high state of a signal input through each of the resistors 31 and 32.

As illustrated in FIG. 6, when at least one of a signal input to one end of the resistor R1 (31) and a signal input to one end of the resistor R2 (32) is in a high state, a voltage of the node "N3" is low. Only when the signal input to one end of the resistor R1 (31) is in a low state and the signal input to one end of the resistor R2 (32) is in a low state, the spike signal is generated at the node "N3", and thereby, the voltage of the node "N3" is high. In this way, the neuron device illustrated in FIG. 5 performs a NOR operation on a signal input to one end of the resistor R1 (31) and a signal input to one end of the resistor R2 (32).

Referring to FIG. 7, a neuron device that performs a NAND operation is composed of a resistor R1 (41), a resistor R2 (42), a diode D1 (43), a diode D2 (44), a capacitor C (45), a resistor R3 (46), an OTS 47, a resistor R4 (48), and a resistor R5 (49). In FIG. 7, a node corresponding to a connection point between a first terminal of two terminals of the OTS 47 and a first terminal of two terminals of the capacitor C (45) is referred to as "N1", a node corresponding to a connection point between a second terminal of the two terminals of the OTS 47 and one end of the resistor R5 (49) is referred to as "N2", and a node corresponding to a connection point between a second terminal of the two terminals of the capacitor C (45) and one end of the resistor R3 (46) is referred to as "N3".

A first input signal among multiple input signals is input through one end of the resistor R1 (41), and the resistor R1 (41) functions as a first dendrite among multiple dendrites. A second input signal among the multiple input signals is input through one end of the resistor R2 (42), and the resistor R2 (42) functions as a second dendrite among the multiple dendrites. Because voltage drops occur while the respective input signals pass through the two resistors 41 and 42, the respective resistors 41 and 42 may simulate a phenomenon in which an external signal is weakened while passing through the dendrite of a biological neuron. In the neuron device illustrated in FIG. 7, the other end of the resistor R1 (41) is connected to a negative terminal of the diode D1 (43), and the other end of the resistor R2 (42) is connected to a negative terminal of diode D2 (44).

The diode D1 (43) is connected between the node "N1" and the other end of the resistor R1 (41) and allows only a current to flow from the node "N1" to the other end of the resistor R1 (41). The diode D2 (44) is connected between the node "N1" and the other end of the resistor R2 (42) and allows only a current to flow from the node "N1" to the other end of the resistor R2 (42). In the neuron device illustrated in FIG. 7, the negative terminal of the diode D1 (43) is connected to the other terminal of the resistor R1 (41), and a positive terminal of the diode D1 (43) is connected to the node "N1". The negative terminal of the diode D2 (44) is connected to the other terminal of the resistor R2 (42), and a positive terminal of the diode D2 (44) is connected to the node "N1".

The capacitor C (45) is connected between the first terminal of OTS 47 and the ground of a spiking neural network, and electric charges are accumulated in the capacitor C (45) according to a voltage of each of the multiple input signals. Charging of the capacitor C (45) may simulate a phenomenon in which a stimulus signal input through the dendrite accumulates in a membrane potential. In the neuron device illustrated in FIG. 7, a first terminal of two terminals of the capacitor C (45) is connected to the first terminal of the OTS 47, that is, the node "N1", and a second terminal of the two terminals of the capacitor C (45) is connected to the ground of the spiking neural network. One end of the resistor R3 (46) is connected to the second terminal of the capacitor C (45), and the other end of the resistor R3 (46) is connected to the ground of the spiking neural network.

The first terminal of the OTS 47 is connected to the first terminal of the capacitor C (45), and the OTS 47 is switched an off state to an on state according to a charging voltage of the capacitor C (45), and accordingly, the OTS 47 simulates the generation of a spike signal according to the accumulation of at least one input signal among the multiple input signals. When a voltage applied to two terminals of the OTS 47 increases and reaches a threshold voltage of the OTS 47, the OTS 47 switches from an off state to an on state. In the neuron device illustrated in FIG. 7, the first terminal of two terminals of the OTS 47 is connected to the first terminal of the capacitor C (45), that is , the node "N1", and the second terminal of two terminals of OTS 47 is connected to one end of the resistor R5 (49), that is, a node "N2".

The resistor R4 (48) has one end connected to the node "N2" and the other end to which an external voltage "Vdd" is applied to turn on the OTS (47) such that a voltage exceeding a threshold voltage of the OTS 47 is applied to the node "N2". The external voltage "Vdd" may be a drive voltage of a spiking neural network. Since a voltage applied to the node "N2" is determined according to resistance of the resistor R4 (48), a voltage exceeding the threshold voltage of the OTS 47 may be applied to the node "N2".

The resistor R5 (49) is connected between the second terminal of the OTS 47 and the ground of the spiking neural network and serves to adjust a refractory period length of the OTS 47. Since a voltage between the two terminals of the OTS 47 is determined according to resistance of the resistor R5 (49), the refractory period length of the OTS 47 may be adjusted. In the neuron device illustrated in FIG. 7, one end of the resistor R5 (49) is connected to the second terminal of the OTS 47, that is, the node "N2", and the other end of the resistor R5 (49) is connected to the ground of the spiking neural network. A voltage of the node "N3" represents a result value of a NAND operation on multiple input signals.

Among three voltage waveforms illustrated in FIG. 8, an upper voltage waveform represents a voltage waveform of the node "N2", a middle voltage waveform represents a voltage waveform of a signal input to one end of the resistor R1 (41), and a lower voltage waveform represents a voltage waveform of a signal input to one end of the resistor R2 (42). The three voltage waveforms are voltage waveforms measured based on the ground of the spiking neural network, and a maximum amplitude is 5 V. The upper voltage waveform represents a voltage waveform measured between the node "N2" and the ground of the spiking neural network, the middle voltage waveform represents a voltage waveform measured between one end of the resistor R1 (41) and the ground of the spiking neural network, and the lower voltage waveform represents a voltage waveform measured between one end of the resistor R2 (42) and the ground of the spiking neural network.

Due to a voltage applied to the node "N1", a current flows only in a direction from the node "N1" toward the other end of the resistor R1 (41) through the diode D1 (43), and likewise, a current flows only in a direction from the node "N1" toward the other end of the resistor R2 (42) through the diode D2 (44). Accordingly, when at least one of a first input signal input through one end of the resistor R1 (41) and a second input signal input through one end of resistor R2 (42) is in a low state (0 V), a voltage of the node "N1" is 0 V. Since a voltage exceeding a threshold voltage of the OTS 47 is applied to the node "N2" by an external voltage "Vdd", in a state where a voltage of the node "N1" is 0 V, a voltage between two terminals of the OTS (47) exceeds the threshold voltage of the OTS 47, and accordingly, the OTS 47 turns on.

As parallel connection resistance of the resistor R1 (41) and the resistor R2 (42) is much greater than resistance of the OTS 47, the OTS 47 turns on, and a voltage drop between two terminals of the resistor R1 (41) and the resistor R2 (42) connected in parallel is greater than a voltage drop between two terminals of the OTS 47, and accordingly, the OTS 35 turns off. When the OTS 47 turns off, the voltage of the node "N1" is 0 V, and accordingly, the OTS 35 turns on again. In order to operate as described above, resistances of the resistor R1 (41) and the resistor R2 (42) and the threshold voltage of the OTS 47 are designed.

In this way, the OTS 47 alternately repeats turning on and turning off, and thereby, voltage oscillation occurs at the node "N1". Due to the voltage oscillation of the node "N1", the capacitor C (45) repeats charging and discharging, and thereby, a spike signal is generated at the node "N3" according to alternate repetition of the turning off and turning on of the OTS 47. As illustrated in FIG. 8, the spike signal generated at the node "N3" has a voltage waveform similar to a waveform in a high state of a signal input through each of the resistors 41 and 42.

When both the first input signal input through one end of the resistor R1 (41) and the second input signal input through one end of the resistor R2 (42) are in a high state (5 V), a current does not flow through the diode D1 (43) and the diode D2 (44), and accordingly, the OTS 47 turns on. Since a voltage exceeding a threshold voltage of the OTS (47) is applied to the node "N2" due to an external voltage "Vdd", the capacitor C (45) is charged, and a charging voltage of the capacitor C (45) gradually increases and converges to 5 V. Since there is no voltage drop between two terminals of the resistor R3 (46) in a state where the charging voltage of capacitor C (45) converges to 5 V, a voltage of the node "N3" is low.

As illustrated in FIG. 8, when at least one of a signal input to one terminal of the resistor R1 (41) and a signal input to one terminal of the resistor R2 (42) is in a low state, a spike signal is generated at the node "N3", and a voltage of the node "N3" is high. A voltage of the node "N2" is low only when a signal input to one terminal of the resistor R1 (41) is in a high state and a signal input to one terminal of the resistor R2 (42) is in a high state. In this way, the neuron device illustrated in FIG. 7 performs a NAND operation on a signal input to one end of the resistor R1 (41) and a signal input to one end of the resistor R2 (42).

Referring to FIG. 9, a neuron device that performs an XOR operation is composed of a resistor R1 (51), a resistor R2 (52), a capacitor C1 (53), a capacitor C2 (54), an OTS 55, and a resistor R3 (56). In FIG. 9, a node corresponding to a connection point between a first terminal of two terminals of the OTS 55 and a first terminal of two terminals of the capacitor C1 (53) is referred to as "N1", a node corresponding to a connection point between a second terminal of the two terminals of the OTS 55 and a first terminal of two terminals of the capacitor C2 (54) is referred to as "N2", and a node corresponding to a connection point between a second terminal of the two terminals of the capacitor C2 (54) and one end of the resistor R3 (56) is referred to as "N3".

A first input signal among multiple input signals is input through one end of the resistor R1 (51), and the resistor R1 (51) functions as a first dendrite among multiple dendrites. A second input signal among the multiple input signals is input through one end of the resistor R2 (52), and the resistor R2 (52) functions as a second dendrite among the multiple dendrites. Because voltage drops occur while the respective input signals pass through the two resistors 51 and 52, the respective resistors 51 and 52 may simulate a phenomenon in which an external signal is weakened while passing through the dendrite of a biological neuron. In the neuron device illustrated in FIG. 9, the other end of the resistor R1 (51) is connected to the node "N2", and the other end of the resistor R2 (52) is connected to the node "N1".

The capacitor C1 (53) is connected between the first terminal of OTS 55 and the ground of a spiking neural network, and electric charges are accumulated in the capacitor C1 (53) according to a voltage of each of the multiple input signals. Charging of the capacitor C1 (53) may simulate a phenomenon in which a stimulus signal input through the dendrite accumulates in a membrane potential. In the neuron device illustrated in FIG. 9, the first terminal of the two terminals of the capacitor C (53) is connected to the first terminal of the OTS 55, that is, the node "N1", and a second terminal of the two terminals of the capacitor C1 (53) is connected to the ground of the spiking neural network.

The capacitor C2 (54) is connected between the second terminal of the OTS 55 and the resistor R3 (56), and electric charges are accumulated in the capacitor C2 (54) according to a voltage of each of the multiple input signals. Charging of the capacitor C1 (54) may simulate a phenomenon in which a stimulus signal input through the dendrite accumulates in a membrane potential. In the neuron device illustrated in FIG. 9, the first terminal of the two terminals of the capacitor C1 (53) is connected to the second terminal of the OTS 55, that is, the node "N2", and the second terminal of the two terminals of the capacitor C1 (53) is connected to one end of the resistor R3 (56), that is, the node "N3".

The OTS 55 has the first terminal connected to the first terminal of the capacitor C153 so as to switch from an off state to an on state according to a charging voltage of the capacitor C1 (53) and has the second terminal connected to the first terminal of capacitor C2 (54) so as to switch from an off state to an on state according to the charging voltage of the capacitor C1 (53), thereby simulates the generation of a spike signal according to the accumulation of at least one input signal among the multiple input signals. When a voltage applied to two terminals of the OTS 55 increases and reaches a threshold voltage of the OTS 14, the OTS 55 switches from an off state to an on state. In the neuron device illustrated in FIG. 9, the first terminal of two terminals of the OTS 55 is connected to the first terminal of the capacitor C1 (53), that is , the node "N1", and the second terminal of the two terminals of the OTS 55 is connected to the first terminal of the capacitor C2 (54), that is, the node "N2".

The resistor R3 (56) is connected between the second terminal of the OTS 55 and the ground of the spiking neural network and serves to control a refractory period length of the OTS 55. Since a voltage between the two terminals of the OTS 55 is determined according to resistance of the resistor R3 (56), the refractory period length of the OTS 5 may be adjusted. In the neuron device illustrated in FIG. 9, one end of the resistor R3 (56) is connected to the second terminal of the capacitor C2 (54), that is, the "N3", and the other end of the resistor R3 (56) is connected to the ground of the spiking neural network. A voltage of node "N3" represents a result value of an XOR operation on multiple input signals.

Among three voltage waveforms illustrated in FIG. 10, an upper voltage waveform represents a voltage waveform of the node "N2", a middle voltage waveform represents a voltage waveform of a signal input to one end of the resistor R1 (51), and a lower voltage waveform represents a voltage waveform of a signal input to one end of the resistor R2 (52). The three voltage waveforms are voltage waveforms measured based on the ground of the spiking neural network, and a maximum amplitude is 5 V. The upper voltage waveform represents a voltage waveform measured between the node "N2" and the ground of the spiking neural network, the middle voltage waveform represents a voltage waveform measured between one end of the resistor R1 (51) and the ground of the spiking neural network, and the lower voltage waveform represents a voltage waveform measured between one end of the resistor R2 (52) and the ground of the spiking neural network.

When both a first input signal input through one end of the resistor R1 (51) and a second input signal input through one end of the resistor R2 (52) are in a low state (0 V) or a high state (5 V), signals of the same voltage are input to the node "N1" and the node "N2". When the signals of the same voltage are input to the node "N1" and the node "N2", there is no voltage difference between the two terminals of the OTS 55, and accordingly, the OTS 55 turns off. When both the first input signal input through one end of the resistor R1 (51) and the second input signal input through one end of the resistor R2 (52) are in a low state, the capacitor C1 (53) and the capacitor C2 (54) are not charged, and accordingly, a voltage of the node "N3" is low.

When both the first input signal input through one end of the resistor R1 (51) and the second input signal input through one end of the resistor R2 (52) are in a high state, the capacitor C1 (53) is charged, and accordingly, a charging voltage of the capacitor C1 (53) increases and converges to 5 V, and at the same time, the capacitor C2 (54) is charged, and accordingly, a charging voltage of the capacitor C2 (54) increases and converges to 5 V. In this case, there is no voltage drop between both ends of the resistor R3 (56) when the charging voltage of the capacitor C2 (54) is converged to 5 V, a voltage of the node "N3" is low. The charging voltage of the capacitor C1(53) does not affect the voltage of the node "N3".

When one of the first input signal input through one end of the resistor R1(51) and the second input signal input through one end of the resistor R2(52) is in a low state (0 V) and the other is in a high state (5 V), a voltage difference between the node "N1" and the node "N2" is 5 V, and accordingly, the OTS 55 turns on. A threshold voltage of the OTS 55 is designed to be less than 5 V and greater than 2.5 V. In this case, a 0-V signal is input to one terminal of the OTS 55 and a 5-V signal is input to the other terminal of the OTS 55, and accordingly, a voltage difference between the two terminals of the OTS 55 decreases rapidly at the moment when the OTS 55 turns on. As the voltage difference between the two terminals of the OTS 55 decreases rapidly, the OTS (55) turns off.

When the OTS 55 turns off, a voltage difference between the node "N1" and the node "N2" is 5 V, and the OTS 55 turns on again. In this way, the OTS 55 alternately repeats turning on and turning off, and thereby, voltage oscillation occurs at the node "N2". Due to the voltage oscillation at the node "N2", the capacitor C2 (54) repeats charging and discharging, and accordingly, a spike signal is generated at the node "N2" as the OTS 14 alternately switches from an off state to an on state. As illustrated in FIG. 10, a spike signal generated at the node "N3" has a voltage waveform similar to a waveform in a high state of a signal input through each of the resistors 51 and 52.

As illustrated in FIG. 10, when both the first input signal input through one end of the resistor R1 (51) and the second input signal input through one end of the resistor R2 (52) are in a low state (0 V) or a high state (5 V), a voltage of the node "N3" is low. When either the first input signal input through one end of the resistor R1 (51) or the second input signal input through one end of the resistor R2 (52) is in a low state (0 V) and the other is in a high state (5 V), a spike signal is generated at the node "N3", and the voltage of the node "N3" is high. In this way, the neuron device illustrated in FIG. 9 performs an XOR operation on a signal input to one end of the resistor R1 (51) and a signal input to one end of the resistor R2 (52).

According to embodiments of the present disclosure described above, a neuron device may be provided which performs a binary logic operation on multiple input signals using an Ovonic threshold switch that simulates the generation of a spike signal according to accumulation of at least one input signal among multiple input signals input through multiple resistors that serve as multiple dendrites. In particular, a neuron device may be provided which performs most binary logic operations, such as an AND operation, an OR operation, a NOR operation, a NAND operation, and an XOR operation in a spiking neural network.

Since a neuron device using a conventional CMOS requires approximately 10 to 20 MOSFETs, there is limitation in terms of miniaturization and energy saving of the neuron device, but the neuron device according to the present disclosure may be implemented as a simple circuit including only a few electronic components, such as a few resistors, one or two capacitors, and two diodes in addition to an OTS, miniaturization and energy saving of the neuron device may be maximized. In this way, since the miniaturization and energy saving of the neuron device may be maximized, the scalability of a spiking neural network may be greatly improved.

The present disclosure is described above, focusing on preferred embodiments thereof. Those skilled in the art will understand that the present disclosure may be implemented in modified forms without departing from the essential characteristics of the present disclosure. Therefore, the disclosed embodiments should be considered from an illustrative rather than a limiting perspective. The scope of the present disclosure is indicated not by the above description but by the claims, and all differences within the equivalent scope should be interpreted as being included in the present disclosure.

What is claimed is:

1. A neuron device of a spiking neural network, comprising:
an Ovonic threshold switch configured to simulate generation of a spike signal according to accumulation of at least one input signal among multiple input signals input through multiple resistors that serve as multiple dendrites,
wherein a binary logic operation is performed on the multiple input signals using the Ovonic threshold switch.

2. The neuron device of claim 1, further comprising:
a capacitor that is charged according to a voltage of each of the multiple input signals,
wherein the Ovonic threshold switch simulates the generation of the spike signal according to the accumulation of the at least one input signal among the multiple input signals by switching from an off state to an on state according to a charging voltage of the capacitor.

3. The neuron device of claim 2, wherein
the capacitor is connected between a first terminal of two terminals of the Ovonic threshold switch and a ground of the spiking neural network.

4. The neuron device of claim 3, further comprising:
a first resistor configured to function as a first dendrite among the multiple dendrites by receiving a first input signal among the multiple input signals through one end of the first resistor; and
a second resistor configured to function as a second dendrite among the multiple dendrites by receiving a second input signal among the multiple input signals through one end of the second resistor.

5. The neuron device of claim 4, further comprising:
a third resistor connected between a second terminal among two terminals of the Ovonic threshold switch and the ground of the spiking neural network and configured to adjust a refractory period length of the Ovonic threshold switch.

6. The neuron device of claim 5, wherein
a first terminal of two terminals of the capacitor is connected to a first terminal among the two terminals of the Ovonic threshold switch, and a second terminal of the two terminals of the capacitor is connected to the ground of the spiking neural network,
another end of the first resistor is connected to a first node corresponding to a connection point between the first terminal of the Ovonic threshold switch and the first terminal of the capacitor, and another end of the second resistor is connected to the first node in parallel with the first resistor, and
a voltage of a second node corresponding to a connection point between the second terminal of the Ovonic threshold switch and one end of the third resistor represents a result value of an AND operation on the multiple input signals.

7. The neuron device of claim 5, wherein
a first terminal of two terminals of the capacitor is connected to the first terminal of the two terminals of the Ovonic threshold switch, a second terminal of the two terminals of the capacitor is connected to the ground of the spiking neural network,
the neuron device further includes a first diode connected between the first node corresponding to the connection point between the first terminal of the Ovonic threshold switch and the first terminal of the capacitor and another end of the first resistor and allowing a current to flow in a direction from another end of the first resistor toward the first node; and a second diode connected between the first node and another end of the second resistor and allowing a current to flow in a direction from the other end of the second resistor toward the first node, and
a voltage of a second node corresponding to a connection point between the second terminal of the Ovonic threshold switch and one end of the third resistor represents a result value of an OR operation on the multiple input signals.

8. The neuron device of claim 5, wherein
a first terminal of two terminals of the capacitor is connected to the first terminal of the two terminals of the Ovonic threshold switch,
the neuron device further includes a fourth resistor having one end connected to a second terminal of the two terminals of the capacitor and another end connected to the ground of the spiking neural network,
another end of the first resistor is connected to a first node corresponding to a connection point of the first terminal of the Ovonic threshold switch and the first terminal of the capacitor, and another end of the second resistor is connected to the first node in parallel with the first resistor, and
a voltage of a second node corresponding to a connection point between the second terminal of the capacitor and one end of the fourth resistor represents a result value of a NOR operation on values of the multiple input signals.

9. The neuron device of claim 8, wherein
the neuron device further includes a fifth resistor having one end connected to a third node corresponding to a connection point between the second terminal of the Ovonic threshold switch and one end of the third resistor, and
an external voltage for turning on the Ovonic threshold switch is applied to another end of the fifth resistor.

10. The neuron device of claim 5, wherein
a first terminal of two terminals of the capacitor is connected to the first terminal of the two terminals of the Ovonic threshold switch,
the neuron device further includes a first diode connected between a first node corresponding to a connection point between the first terminal of the Ovonic threshold switch and a first terminal of the capacitor and another terminal of the first resistor, and allowing only a current to flow in a direction from the first node toward the other terminal of the first resistor; a second diode connected between the first node and another terminal of the second resistor and allowing only a current to flow in a direction from the first node to the other terminal of the second resistor; and a fourth resistor having one end connected to a second terminal of the two terminals of the capacitor and another end connected to the ground of the spiking neural network, and
a voltage of a second node corresponding to a connection point of the second terminal of the capacitor and one end of the fourth resistor represents a result value of a NAND operation on values of the multiple input signals.

11. The neuron device of claim 10, wherein
the neuron device further includes a fifth resistor having one end connected to a third node corresponding to a connection point between the second terminal of the Ovonic threshold switch and one end of the third resistor, and
an external voltage for turning on the Ovonic threshold switch is applied to another end of the fifth resistor.

12. The neuron device of claim 5, wherein
the capacitor is a first capacitor,
the neuron device further includes a second capacitor connected between the second terminal of the Ovonic threshold switch and the third resistor,
another end of the second resistor is connected to a first node corresponding to a connection point between the first terminal of the Ovonic threshold switch and a first terminal of two terminals of the first capacitor,
another end of the first resistor is connected to a second node corresponding to a connection point between the second terminal of the Ovonic threshold switch and a first terminal of two terminals of the second capacitor, and
a voltage of a third node corresponding to a connection point between a second terminal of the second capacitor and one end of the third resistor represents a result value of an XOR operation on values of the multiple input signals.
